(19) United States
(12) Patent Application Publication
(10) Pub. No.: US 2020/0278608 A1
(43) Pub. Date: Sep. 3, 2020

(54) COLORING COMPOSITION AND COLOR FILTER

(71) Applicant: DIC Corporation, Tokyo (JP)

(72) Inventors: Kazushi Suzuki, Sakura-shi (JP); Ryosuke Asami, Sakura-shi (JP)

(73) Assignee: DIC Corporation, Tokyo (JP)

(21) Appl. No.: 16/650,517

(22) PCT Filed: Nov. 27, 2018
(86) PCT No.: PCT/JP2018/043508

§ 371 Date: Mar. 25, 2020

(30) Foreign Application Priority Data
Dec. 14, 2017 (JP) 2017-239533

(51) Int. Cl. G03F 7/004; G03F 7/00; C09B 1/12; C09B 1/06; G02B 1/04

(52) U.S. Cl. CPC G03F 7/0045; G03F 7/0007; G03F 7/0048; G02B 5/20; C09B 1/06; G02B 1/04; C09B 1/12

(57) ABSTRACT

A problem to be solved by the present invention is to provide a coloring composition which contains a threne compound unlikely to be highly dispersed in glycol solvents used in color filter-preparing steps in recent years, which allows the threne compound to be highly dispersed in a glycol solvent, and which can be used without causing an undesirable influence such as a curing failure in a color filter-preparing step. The above problem is solved by providing a coloring composition containing a specific anthraquinone derivative, a threne compound, and a glycol organic solvent.

### TECHNICAL FIELD

The present invention relates to a coloring composition and a color filter containing the same.

### BACKGROUND ART

Threne compounds, which are used as various coloring components, are required to have higher dispersibility in media depending on applications.

In particular, in color filter applications, the dispersibility of a coloring component is directly linked to display performance and therefore the requirement of dispersibility is higher as compared to applications such as general-purpose paints and printing inks.

For media in photosensitive resin compounds generally used to manufacture color filters, glycol solvents are exclusively selected because of low harmful effects on humans and good heat-drying properties.

The threne compounds are known to be unlikely to be highly dispersed in the glycol solvents and attempts have hitherto been made to improve dispersibility using a dye or pigment derivative (hereinafter simply referred to as a derivative) in combination therewith. However, selecting those incompatible with the glycol solvents exerts an undesirable influence on dispersion in reverse in some cases. Therefore, additives used in combination cannot possibly withstand practical use if the additives are not compatible with the glycol solvents.

in applications, such as color filter applications, significantly affected in quality by a slight change in hue, it is not preferable to use a general-purpose derivative with high tinting strength.

In general, a photolithographic method is used to manufacture a color filter. This method includes a step in which pattern exposure is performed in such a manner that a photosensitive composition containing a coloring component such as pigment is applied to a transparent substrate for color filters, is heat-dried, and is then irradiated with an ultraviolet ray through a photomask. In order to appropriately perform curing using the ultraviolet ray without unevenness, it is desirable that the coloring component absorbs the ultraviolet ray as little as possible.

Herein, Patent Literature 1 describes a composition containing a threne pigment and sulfonic acid derivatives of various pigments. Patent Literature 2 describes a pigment composition containing an anthraquinone derivative and a colorant.

PTL 1: Japanese Unexamined Patent Application Publication (Translation of PCT Application) No. 2004-522820

PTL 2: Japanese Unexamined Patent Application Publication No. 2005-213403

### SUMMARY OF INVENTION

### Technical Problem

However, in a method described in Patent Literature 1, a sulfonic acid derivative of the threne pigment or a sulfonic acid derivative of another pigment absorbs light in the visible region unlike the threne pigment itself and therefore there is a problem in that hue varies as compared to the threne pigment alone. Furthermore, the absorption of an ultraviolet ray by a derivative is high and therefore the absorption of an ultraviolet ray by a coloring composition is also high; hence, there is a problem in that ultraviolet curing is inhibited in color filter applications. In a method described in Patent Literature 2, a solvent used is a polar solvent with a dielectric constant of 15 or more and the high dispersion of a threne compound cannot be achieved.

A problem to be solved by the present invention is to provide a coloring composition which contains a threne compound unlikely to be highly dispersed in glycol solvents used in color filter-preparing steps in recent years, which allows the threne compound to be highly dispersed in a glycol solvent, and which can be used without causing an undesirable influence such as a curing failure in a color filter-preparing step.

### Solution to Problem

The inventors have performed intensive investigations and, as a result, have found that the above problems can be solved using a coloring composition containing a specific anthraquinone derivative, threne compound, and glycol organic solvent described below, leading to the completion of the present invention.

That is, the present invention relates to “Item 1. A coloring composition (hereinafter referred to as the coloring composition according to the present invention in some cases) containing an anthraquinone derivative represented by General Formula (1) below:

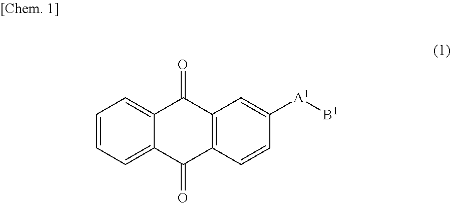

(in Formula (1), A¹ is a single bond, —CONH—R¹—, or —SO₂NH—R—;

R¹ and R² are independently a divalent hydrocarbon group which may have a single bond or a substituent and which contains one to 20 carbon atoms; B¹ is —SO₃M.nH₂O or —COOM.nH₂O; N is one equivalent of a monovalent to trivalent cation; and n is an integer of 0 to 5),
a threne compound represented by General Formula (2) below:

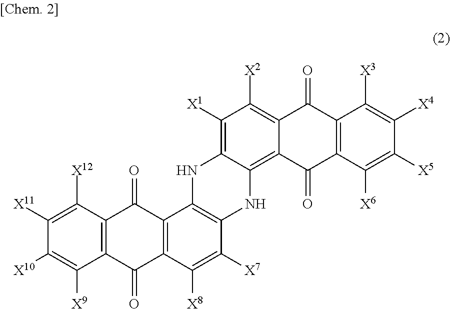

(in Formula (2), X¹ to X² are independently a hydrogen atom or a halogen atom), and a glycol organic solvent represented by General Formula (3) below:

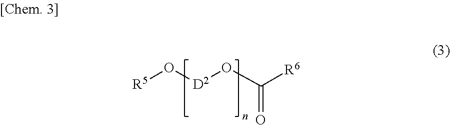

(in Formula (3), D² is a divalent hydrocarbon group which may have a substituent and which contains one to 20 carbon atoms, R⁵ is a monovalent hydrocarbon group which may have a hydrogen atom or a substituent, R⁶ is a monovalent hydrocarbon group which may have a substituent, and n is an integer of 1 to 5).

Item 2. In the coloring composition specified in Item 1, the threne compound is at least one selected from the group consisting of Pigment Blue 60, Vat Blue 4, Pigment Blue 64, and Vat Blue 6.
Item 3. In the coloring composition specified in Item 1 or 2, the anthraquinone derivative is a compound represented by Genera Formula (1-1) below:

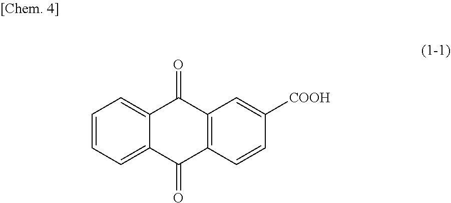 [SMILES: O=C(O)c1ccc2c(c1)C(=O)c1ccccc1C2=O]

or a compound represented by General Formula (1-2) below:

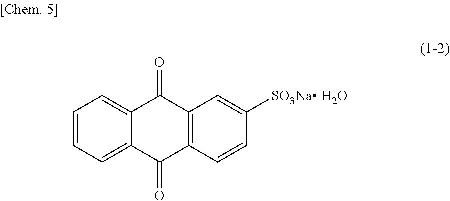

Item 4. Furthermore, the present invention relates to the coloring composition specified in any one of Items 1 to 3, wherein the glycol organic solvent is propylene glycol monomethyl ether acetate.

Furthermore, the present invention relates to a color filter containing the coloring composition”.

### Advantageous Effects of Invention

A coloring composition according to the present invention is a coloring composition which allows a threne compound that is unlikely to be highly dispersed in an organic solvent to be highly dispersed and which can be used without causing an undesirable influence such as a curing failure or a change in hue in a color filter-preparing step. Using this enables an excellent color filter to be obtained.

### DESCRIPTION OF EMBODIMENTS

The present invention is a coloring composition containing a specific anthraquinone derivative, a threne compound, and a glycol organic solvent.

The anthraquinone derivative, which is used in the present invention, has one specific substituent (an acidic functional group below) at a specific substitution position (the 2-position). The coloring composition can be obtained by dispersing the anthraquinone derivative and the threne compound, which is described below, in the glycol solvent such that the threne compound is highly dispersed.

The dispersion mechanism of the threne compound probably passes through a stage in which an anthraquinone skeleton moiety in the anthraquinone derivative is adsorbed on an anthraquinone skeleton moiety in the threne compound and an acidic functional group moiety in the anthraquinone derivative is then adsorbed on a basic group moiety in a dispersant by an acid-base interaction. This enables a dispersion effect due to the steric hindrance or electrostatic repulsion of the dispersant to be received. As a result, the threne compound is probably highly dispersed in the glycol organic solvent.

Herein, substituents can be introduced into the 1- and 2-positions of an anthraquinone compound and countless combinations of the substituents are conceivable. The inventors have found that having an acidic functional group (-A¹-B¹) below at a 2-position rather than a 1-position among these allows the threne compound to exhibit particularly excellent dispersibility. This finding is due to trial and error by the inventors. Although a mechanism is unclear, one having an acidic functional group at the 1-position of anthraquinone probably does not sufficiently receive a dispersion effect because the acidic functional group adsorbed on the threne compound is present at a distance spatially close to a carbonyl group in the threne compound and therefore the interaction between the acidic functional group or a functional group, adsorbed on the acidic functional group, in a dispersant and the carbonyl group occurs to fix a position such that the spatial expanse of polymer chains of the dispersant is limited. However, one having an acidic functional group at the 2-position of anthraquinone probably exhibits high dispersibility (reduced viscosity) because the acidic functional group adsorbed on the threne compound is present at a position spatially apart from the carbonyl group in the threne compound and therefore the above-mentioned interaction does not occur.

In a case where, even if a compound has an acidic functional group at the 2-position of anthraquinone, the compound further has another acidic functional group (a di-substituted compound), steric hindrance occurs during adsorption on a colorant or the dispersant. However, a mono-substituted compound probably exhibits high dispersibility (reduced viscosity) because the steric hindrance thereof is reduced and therefore the adsorbability is increased.

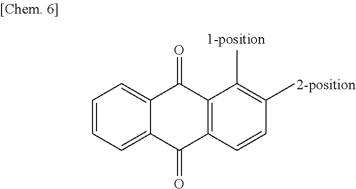 [SMILES: Cc1ccc2c(c1C)C(=O)c1ccccc1C2=O]

The glycol solvent has such polarity that exhibits an adequate affinity for the anthraquinone derivative and the dispersant and therefore can probably implement a high dispersion system due to an adequate interaction between the threne compound, the anthraquinone derivative, the dispersant, and a solvent.

The anthraquinone derivative, which is used in the present invention, is represented by General Formula (1) below:

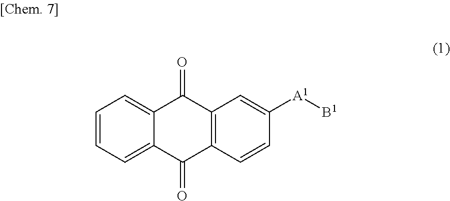

(in Formula (1), A¹ is a single bond, —CONH—R¹—, or —SO₂NH—R²—; R¹ and R² are independently a divalent hydrocarbon group which may have a single bond or a substituent and which contains one to 20 carbon atoms; B¹ is —SO₃M.nH₂O or —COOM.nH₂O; M is one equivalent of a monovalent to trivalent cation; and n is an integer of 0 to 5)

Herein, examples of the divalent hydrocarbon group, which may have a single bond or a substituent and contains one to 20 carbon atoms, include a methylene group, an ethylene group, a propylene group, a butylene group, a hexylene group, a cyclohexylene group, a phenylene group, a naphthylene group, an vinylene group, and an allylene group. The term “substituent” can refer to, but is not limited to, for example, a halogen atom, a nitro group, a cyano group, a hydroxy group, a carboxy group, a sulfo group, an amino group, and the like.

Herein, the term “one equivalent of a monovalent to trivalent cation” can refer to, but is not limited to, one mole of hydrogen ions, one mole of sodium (I) ions, one-third mole of aluminium (II) ions, one-half mole of calcium (II) ions, one mole of ammonium ions, and the like per mole of —SO₂— or —COO—.

In particular, compounds below can be cited.

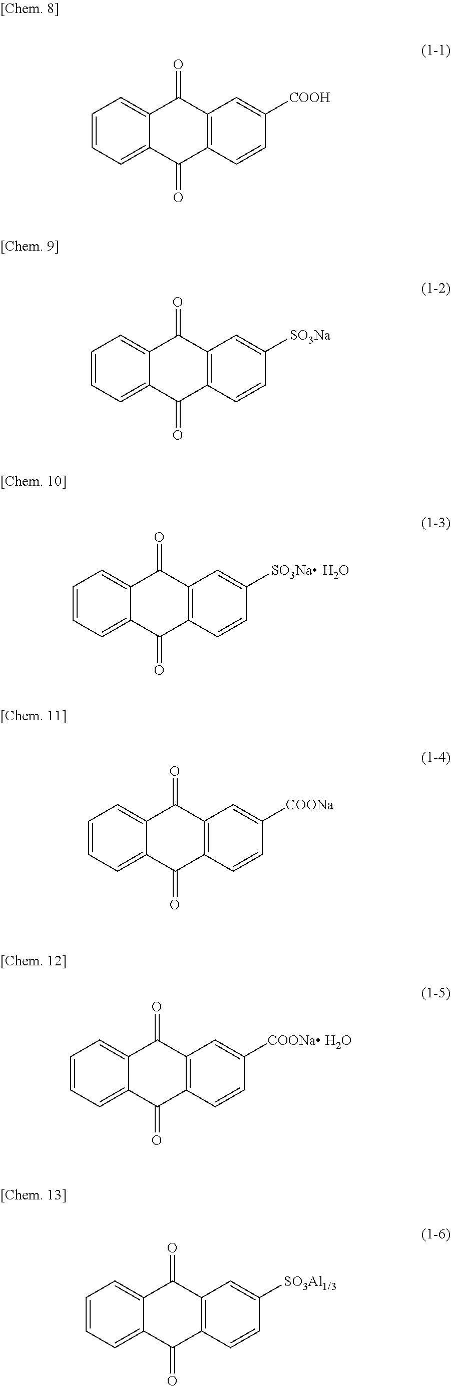

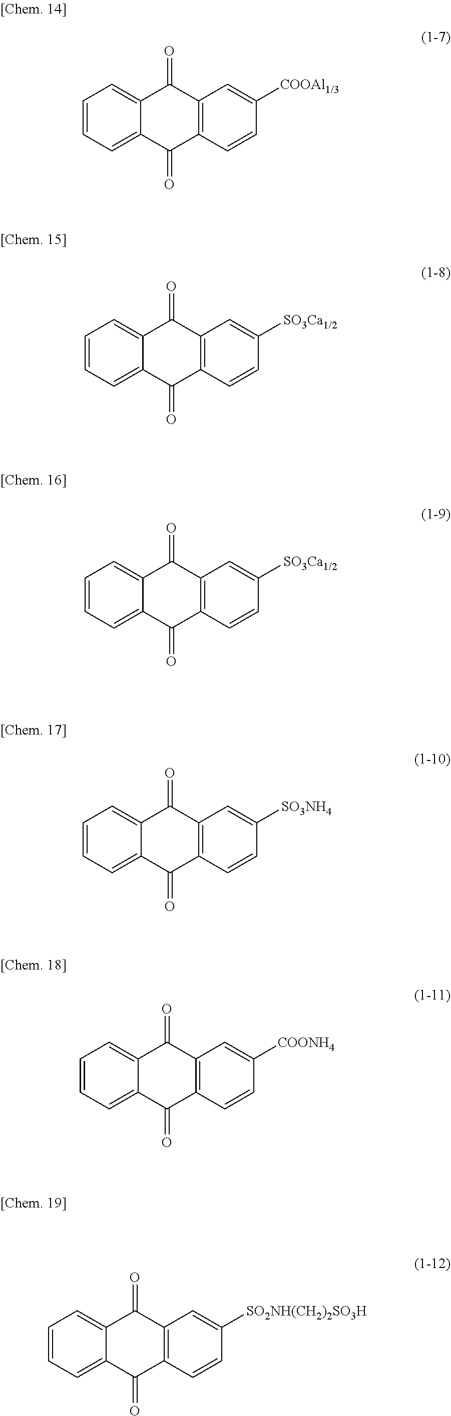

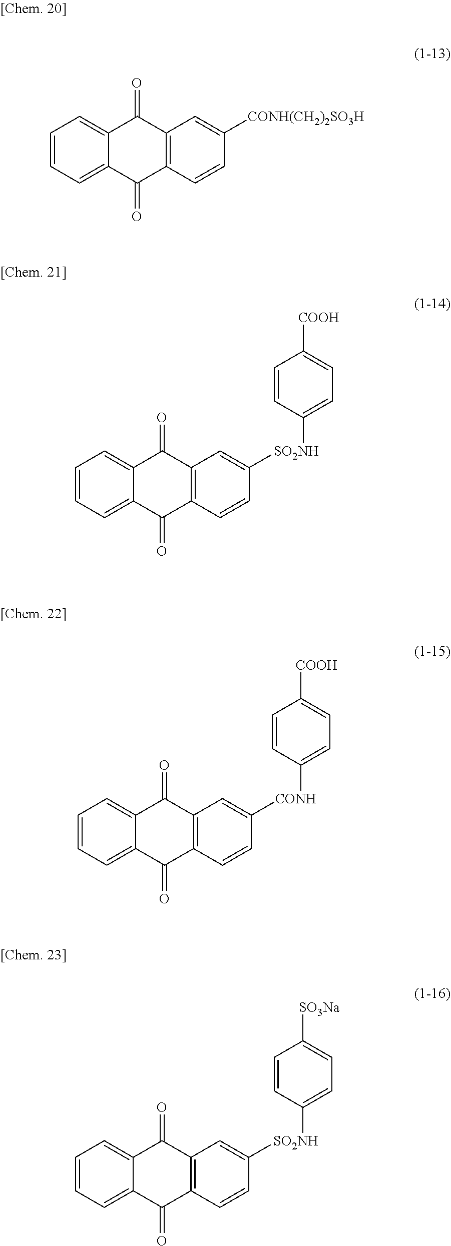

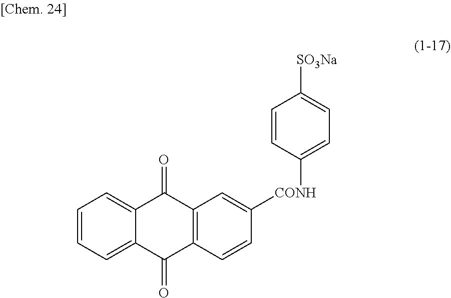

More preferably, a compound represented by General Formula (1-1) below:

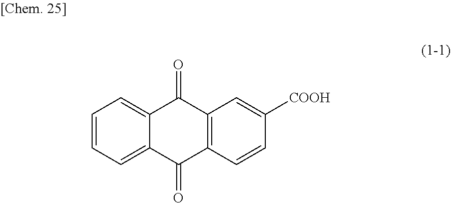

or a compound represented by General Formula (1-2) below:

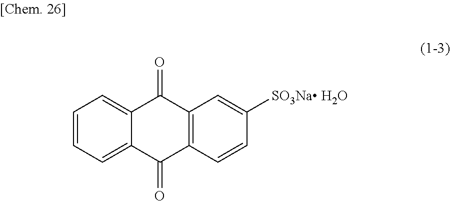

is cited. This is because the compound is advantageous from the viewpoint that the molecular weight is low, the percentage of the molecular weight of an acidic functional group in the molecular weight of the compound is large, and high dispersibility is exhibited in a small additive amount.

The anthraquinone derivative generally has lower absorbance in the visible region as compared to pigment derivatives and exhibits a small change in hue from a colorant (the threne compound below) alone eve after a derivative is added. The anthraquinone derivative has low absorbance in the ultraviolet region and therefore does not inhibit ultraviolet curing. In terms of these, the anthraquinone derivative is suitable particularly for color filter applications.

These can use commercially available products or those synthesized in accordance with known methods.

The threne compound, which is used in the present invention, is represented by General Formula (2) below:

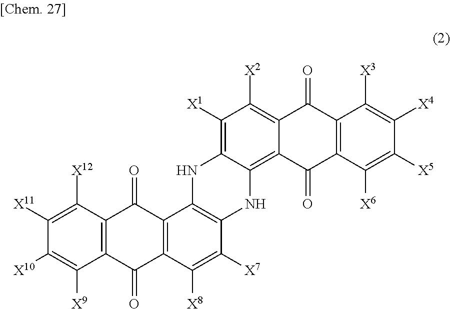

(in Formula (2), X¹ to X¹² are independently a hydrogen atom or a halogen atom). For example, Pigment Blue 60, Vat Blue 4, Pigment Blue 64, and Vat Blue 6 are cited. These can use commercially available products or those synthesized in accordance with known methods.

Incidentally, some pigments having a similar structure, which is different from Formula (2), are known. If the threne compound, which is used in the present invention, is used in combination with pigment with a structure other than a structure represented by Formula (2), an effect similar to that of the present invention is not obtained. For example, C.I. Pigment No. 177, in which anthraquinone structures are linked together with a single bond, is not effective in obtaining an excellent effect provided by the coloring composition according to the present invention as illustrated in a comparative example below. Since the threne compound has a planar structure, it is inferred that the spatial positions of an adsorbed derivative and dispersant are fixed and the aggregation of the threne compound due to the approach of a crystal face can be suppressed by polymer chains in the dispersant. However, although C.I. Pigment No. 177, in which the anthraquinone structures are linked together with the single bond, as well as the threne compound, can adsorb the anthraquinone derivative because of the anthraquinone structures in the skeleton thereof, a single bond moiety can freely rotate. Therefore, it is inferred that faces of the polymer chains in the dispersant that have low steric hindrance approach each other and the effect of suppressing aggregation is not obtained.

Examples of the glycol organic solvent include glycol ethers and glycol esters. Examples of the glycol ethers include ethylene glycol monomethyl ether, ethylene glycol monoethyl ether, ethylene glycol monobutyl ether, diethylene glycol monoethyl ether, diethylene glycol monobutyl ether, triethylene glycol monomethyl ether, triethylene glycol monoethyl ether, triethylene glycol monobutyl ether, and propylene glycol t-butyl ether. Examples of the glycol esters include ethylene glycol acetate, ethylene glycol monomethyl ether acetate, ethylene glycol monoethyl ether acetate, ethylene glycol monobutyl ether acetate, diethylene glycol monoethyl ether acetate, diethylene glycol monobutyl ether acetate, triethylene glycol monomethyl ether acetate, triethylene glycol monoethyl ether acetate, triethylene glycol monobutyl ether acetate, and tripropylene glycol methyl ether.

in order to allow the coloring composition to have low viscosity and excellent workability, at least propylene glycol monomethyl ether acetate is preferably used as the glycol solvent, which is contained in the coloring composition.

One having low volatility at room temperature and good heat-drying properties is preferable. That is, the glycol solvent preferably has a boiling point of 100° C. to 160° C. and more preferably a boiling point of 130° C. to 150° C. Propylene glycol monomethyl ether acetate and the like are cited as solvents with a boiling point of 130° C. to 150° C.

The coloring composition according to the present invention can be used in applications such as coloring members for displays.

Preferable usage examples include, for example, light-shielding members for displays.

The light-shielding members for displays are materials for blocking light in the visible region or light emitted from light-emitting members, such as backlights, in displays. In particular, there are black matrixes, TFT light-shielding films, black masks, black seals, black column spacers, field-limiting layers in ELDs, and the like.

The coloring composition according to the present invention may be mixed with another colorant such as an organic pigment, an inorganic pigment, or dye. Examples of the colorant mixed therewith include C.I. Pigment Orange 64 and C.I. Pigment Red 179.

If blackness required for target black matrixes or the like is obtained, pigments below may be further used in combination. Examples of color pigments are described below.

As a blue pigment which may be further added, for example, C.I. Pigment Blues 1, 1:2, 9, 14, 15, 15:1, 15:2. 15:3. 15:4, 15:6, 16, 17, 19, 27, 28, 29, 33, 35, 36, 56, 56:1, 61, 61:1, 62, 63, 66, 67, 68, 71, 72, 73, 74, 75, 76, 78, 79, 80, and the like can be cited.

As a yellow pigment, for example, C.I. Pigment Yellows 1, 1:1, 2, 3, 4, 5, 6, 9, 10, 12, 13, 14, 16, 17, 24, 31, 32, 34, 35, 35:1, 36, 36:1, 37, 37:1, 4, 41, 42, 43, 48, 53, 55, 61, 62, 62:1, 63, 65, 73, 74, 75, 81, 83, 87, 93, 94, 95, 97, 100, 101, 104, 105, 10, 1, 110, 11, 116, 117, 119, 120, 126, 127, 127:1, 128, 129, 130, 133, 134, 136, 138, 139, 142, 147, 148, 150, 151, 153, 154, 155, 157, 158, 159, 160, 161, 162, 163, 164, 165, 166, 167, 168, 169, 170, 172, 173, 174, 175, 176, 180, 10, 181, 182, 183, 184, 185, 188, 189, 190, 191, 191:1, 192, 193, 194, 195, 196, 197, 198, 199, 200, 202, 203, 204, 205, 206, 207, 208, 213, 214, 228, 229, 231, and the like can be cited. Among these, C.I. Pigment Yellows 83, 117, 129, 138, 139, 150, 154, 155, 180, 185, 228, and 231 are preferably cited and C.I. Pigment Yellows 83, 138, 139, 150, 155, 185, 228, and 231 can be more preferably cited.

As an orange pigment, for example, C.I. Pigment Oranges 1, 2, 5, 13, 16, 17, 19, 20, 21, 22, 23, 24, 34, 36, 33, 39, 43, 46, 48, 49, 61, 62, 64, 65, 67, 68, 69, 70, 71, 72, 73, 74, 75, 77, 78, 79, 81, and the like can be cited. Among these, C.I. Pigment Oranges 36, 38, 60, 62, 64, and 72 can be preferably cited.

As a brown pigment, for example, C.I. Pigment Browns 23, 25, 41, and the like can be cited.

As a red pigment, for example, C.I. Pigment Reds 1, 2, 3, 4, 5, 6, 7, 8, 9, 12, 14, 15, 16, 17, 21, 22, 23, 31, 32, 37, 38, 41, 47, 48, 43:1, 48:2, 48:3, 48:4, 49, 49:1, 49:2, 50:1, 52:1, 52:2, 53, 53:1, 53:2, 53:3, 57, 57:1, 57:2, 58:4, 60, 63, 63:1, 63:2, 64, 64:1, 58, 59, 81, 81:1, 81:2, 81:3, 81:4, 83, 88, 90:1, 101, 101:1, 104, 108, 108:1, 109, 112, 113, 114, 122, 123, 144, 146, 147, 149, 151, 166, 168, 169, 170, 172, 173, 174, 175, 176, 177, 178, 179, 181, 184, 185, 187, 188, 190, 193, 194, 200, 202, 206, 207, 208, 209, 210, 213, 214, 21, 220, 221, 224, 230, 231, 22, 233, 235, 236, 237, 238, 239, 242, 243, 245, 47, 249, 250, 251, 253, 254, 255, 256, 257, 258, 259, 260, 262, 263, 264, 265, 266, 267, 268, 269, 270, 271, 7, 273, 274, 275, 276, 279, and the like can be cited. Among these, C.I. Pigment Reds 48:1, 122, 168, 177, 179, 202, 206, 207, 209, 224, 242, 254, and 272 are preferably cited and C.I. Pigment Reds 177, 179, 209, 224, 254, and 272 can be more preferably cited.

As a violet pigment, for example, C.I. Pigment Violets 1, 1:1, 2, 2:2, 3, 3:1, 3:3, 5, 5:1, 14, 15, 16, 19, 23, 25, 27, 29, 31, 32, 37, 39, 42, 44, 47, 49, 50, and the like can be cited. Among these, C.I. Pigment Violets 19, 23, and 29 are preferably cited and C.I. Pigment Violets 23 and 29 can be more preferably cited.

As a green pigment, for example, C.I. Pigment Greens 1, 2, 4, 7, 8, 10, 13, 14, 15, 17, 18, 19, 26, 36, 45, 48, 50, 51, 54, 55, 58, 59, 62, 63, and the like can be cited. Among these, C.I. Pigment Greens 7 and 36 can be preferably cited.

The coloring composition according to the present invention can be obtained in such a manner that the anthraquinone derivative, the threne compound, and the glycol solvent, which are used in the present invention, are used as essential components and a resin dispersant having a basic group is mixed therewith as required.

The anthraquinone derivative is contained within the range of 0.1 parts to 20 parts per 100 parts of the threne compound. In consideration of tinting strength and productivity, the anthraquinone derivative is preferably contained within the range of three parts to ten parts. The anthraquinone derivative may be added in a step of pulverizing a colorant or after the colorant is washed and is purified subsequently to the pulverizing step.

Methods for treating the anthraquinone derivative include a method in which the anthraquinone derivative is dissolved with a solid or an alkali and is adsorbed on the surface of the threne compound in an acidic state. When being solid, the anthraquinone derivative is added to a wet cake containing the pulverized threne compound and a solvent such as water. The anthraquinone derivative is usually dissolved with the alkali at a pH of 8 to 12 and is then mixed with the pulverized threne compound in slurry. Thereafter, the system is adjusted to an acidic pH, usually a pH of 3 to 5, whereby the anthraquinone derivative is precipitated on the surface of the threne compound. Various additives other than the anthraquinone derivative may be added when the coloring composition according to the present invention is produced. In particular, a photocurable or heat-curable resin, a surfactant, a dispersant, rosin, and the like can be cited.

In a case where these coloring compositions are dispersed in the glycol solvent, the resin dispersant having the basic group is used in combination as required for the purpose of enhancing dispersibility and dispersion stability. The resin dispersant having the basic group is bonded due to an acidic group and basic group of the anthraquinone derivative, has a function that a compatible moiety extends into a dispersion medium to form a dispersion, and is different from an alkali-soluble resin and photopolymerizable monomer used to prepare a photosensitive composition below.

As the resin dispersant having the basic group, those having a basic group and a polymer chain can be cited. As the basic group, for example, a tertiary amino group and a quaternary ammonium group can be cite. As the polymer chain, for example, a polyurethane resin, polyethyleneimine, a polyoxyethylene glycol diester, an acrylic resin, a polyester resin, and the like can be cited. In particular, a polyester resin-type dispersant and/or acrylic resin dispersant containing either or both of a tertiary amino group and a quaternary ammonium group is preferable in terms of dispersibility, heat resistance, and lightfastness.

As particular examples of resin dispersants having various basic groups, Ajisper (produced by Ajinomoto Fine-Techno. Co. Inc.), EFKA (produced by BASF Company), DISPERBYK (produced by BYK Chemie GmbH), BYKLPN (produced by BYK Chemie GmbH), DISPARLON (produced by Kusumoto Chemicals, Ltd.), SOLSPERSE (produced by The Lubrizol Corporation), KP (produced by Shin-Etsu Chemical Co., Ltd.), and POLYFLOW (produced by Kyoeisha Chemical Co., Ltd.), which are trade names, and the like can be cited. These dispersants may be used alone or in combination at an arbitrary ratio.

The resin dispersant having the basic group is usually 30 parts to 60 parts per 100 parts in terms of the sum of the masses of colorants and preferably 38 parts to 52 parts.

Examples of the glycol solvent, which is used herein, include glycol ethers and glycol esters. Examples of the glycol ethers include ethylene glycol monomethyl ether, ethylene glycol monoethyl ether, ethylene glycol monobutyl ether, diethylene glycol monoethyl ether, diethylene glycol monobutyl ether, triethylene glycol monomethyl ether, triethylene glycol monoethyl ether, triethylene glycol monobutyl ether, and propylene glycol t-butyl ether. Examples of the glycol esters include ethylene glycol acetate, ethylene glycol monomethyl ether acetate, ethylene glycol monoethyl ether acetate, ethylene glycol monobutyl ether acetate, diethylene glycol monoethyl ether acetate, diethylene glycol monobutyl ether acetate, triethylene glycol monomethyl ether acetate, triethylene glycol monoethyl ether acetate, triethylene glycol monobutyl ether acetate, and tripropylene glycol methyl ether.

When a photosensitive composition for forming a black matrix by a photolithographic system is prepared using the coloring composition, at least propylene glycol monomethyl ether acetate is preferably used as an organic solvent contained in the coloring composition in order to allow the photosensitive composition to have low viscosity, excellent application properties, excellent workability, and excellent discharge properties.

In order to prepare the coloring composition, glycol solvents may be used alone or in combination at an arbitrary ratio.

Another organic solvent may be added unless the dispersibility of the threne compound is impaired.

Examples of the organic solvent that can be added include diisopropyl ether, mineral spirits, n-pentane, amyl ether, ethyl caprylate, n-hexane, diethyl ether, isoprene, ethyl isobutyl ether, butyl stearate, n-octane, Varsol #2, Apco #18 Solvent, diisobutylene, amyl acetate, butyl acetate, Apco thinners, butyl ether, diisobutyl ketone, methylcyclohexene, methyl nonyl ketone, propyl ether, dodecane, Socal Solvent No. 1, Socal Solvent No. 2, amyl formate, dihexyl ether, diisopropyl ketone, Solvesso #150, (n-, sec-, t-)butyl acetate, hexene, Shell TS28 Solvent, butyl chloride, ethyl amyl ketone, ethyl benzoate, amyl chloride, ethyl orthoformate, methoxymethylpentanone, methyl butyl ketone, methyl hexyl ketone, methyl isobutylate, benzonitrile, ethyl propionate, methyl cellosolve acetate, methyl isoamyl ketone, n-amyl methyl ketone (2-heptanone), methyl isobutyl ketone, propyl acetate, amyl acetate, amyl formate, bicyclohexyl, dipentene, methoxymethylpentanol, methyl amyl ketone, methyl isopropyl ketone, propyl propionate, methyl ethyl ketone, methyl cellosolve, ethyl cellosolve, ethyl cellosolve acetate, carbitol, cyclohexanone, ethyl acetate, propylene glycol, 3-methoxypropionic acid, 3-ethoxypropionic acid, methyl 3-ethoxypropionate, ethyl 3-ethoxypropionate, methyl 3-methoxypropionate, ethyl 3-methoxypropionate, propyl 3-methoxypropionate, butyl 3-methoxypropionate, diglyme, ethylcarbitol, butylcarbitol, 3-methoxybutanol, 3-methyl-3-methoxybutanol, 3-methoxybutyl acetate, and 3-methyl-3-methoxybutyl acetate.

in the coloring composition according to the present invention, the organic solvent is used usually in an amount of 300 parts to 800 parts per 100 parts in terms of the sum of the masses of colorants of colors and preferably in an amount of 400 parts to 600 parts.

A pigment derivative or the like other than the anthraquinone derivative (a derivative represented by Formula (1)), which is used in the present invention, can be used as required. Examples of a substituent of the pigment derivative include a sulfo group; a sulfonamide group; quaternary salts thereof; a phthalimidomethyl group; a dialkylaminoalkyl group; a hydroxy group; a carboxy group; and those in which an amide group or the like is bonded directly to a pigment skeleton or indirectly thereto with an alkyl group, an aryl group, a heterocyclic group, or the like therebetween.

The coloring composition can be prepared by stirring and mixing the threne compound, which is used in the present invention, the anthraquinone derivative, which is used in the present invention, the glycol solvent, which is used in the present invention, and the resin dispersant having the basic group as required or can be prepared in such a manner that the above mixture is shaken for a necessary time in the presence of various grinding media such as beads and rods and is dispersed and the media are removed by filtration. For the order of mixing the threne compound, the anthraquinone derivative, the glycol solvent, and the resin dispersant having the basic group, all may be mixed together or a mixture of the threne compound and the anthraquinone derivative mixed in advance and a mixture of the glycol solvent and the resin dispersant having the basic group mixed in advance may be stirred and mixed together again.

The coloring composition can be used for black matrixes or black masks for color filters that are constituent members of displays, column spacers or black seals for liquid crystal layers, TFT light-shielding films, field-limiting layers in ELDs, and other members that need to shield displays from light by a conventionally known method.

A representative method for manufacturing a color filter is a photolithographic method. A black matrix is a method in which the photosensitive composition prepared from the coloring composition according to the present invention as described below is applied to a transparent substrate for color filters, is heat-dried (prebaked), and is then irradiated with an ultraviolet ray through a photomask such that pattern exposure is performed so as to cure a photocurable compound on a location corresponding to a black matrix section; an unexposed portion is developed with a developer; a non-pixel section is removed; and pixel sections are fixed to the transparent substrate. The black matrix section is formed on the transparent substrate by this method so as to be composed of a cured colored film of the photosensitive composition. RGB pixel sections can be prepared from photosensitive compositions prepared from color organic pigments with a large specific surface area in substantially the same manner as the above.

Examples of a method for applying the photosensitive composition below to the transparent substrate, such as glass, include a spin coating method, a roll coating method, a slit coating method, and an ink jet method.

Though conditions for drying a coating film of the photosensitive composition applied to the transparent substrate vary depending on the type of components, the blending ratio, or the like, the coating film is usually dried at 50° C. to 150° C. for about one minute to 15 minutes. This heat treatment is generally referred to as “prebaking”. As light used to photocure the photosensitive composition, an ultraviolet ray with a wavelength of 200 nm to 500 nm or visible light is preferably used. Various light sources emitting light in this wavelength range can be used.

Examples of a development method include a paddle method, a dipping method, and a spraying method. After the photosensitive composition is exposed to light and is developed, the transparent substrate provided with a black matrix or a necessary color pixel section is water-washed and is dried. The color filter obtained in this manner is heat-treated (post-baked) at 100° C. to 280° C. for a predetermined time using a heater such as a hotplate or an oven, whereby a volatile component in a colored coating film is removed and an unreacted photocurable compound remaining in the cured colored film of the photosensitive composition is heat-cured, so that the color filter is completed.

A photosensitive composition for forming the black matrix section of the color filter can be prepared in such a manner that the coloring composition according to the present invention, the alkali-soluble resin, the photopolymerizable monomer, and a polymerization initiator are used as essential components and are mixed together.

In a case where a colored resin film forming the black matrix section is required to have toughness sufficient to withstand baking and the like performed in the actual manufacture of color filters, it is essential to use not only the photopolymerizable monomer but also the alkali-soluble resin to prepare the photosensitive composition. In a case where the alkali-soluble resin is used, an organic solvent used is preferably one dissolving the same.

A method for producing the photosensitive composition is generally a method in which the coloring composition according to the present invention is prepared in advance and the alkali-soluble resin, the photopolymerizable monomer, and the polymerization initiator are added thereto such that the photosensitive composition is obtained.

Examples of the alkali-soluble resin, which is used to prepare the photosensitive composition, include carboxy group or acidic hydroxy group-containing resins such as novolac phenol resins, alkyl (meth)acrylate-(meth)acrylic acid copolymers, styrene-(meth)acrylic ac copolymers, and styrene-maleic acid copolymers. Incidentally, in the present invention, the term “(meth)acrylic” is a generic name for acrylic and methacrylic.

In particular, in order to increase the heat resistance of a cured film, an alkali-soluble resin containing an imide structure, styrene polymerization units, and (meth)acrylic acid polymerization units is preferably used.

This alkali-soluble resin does not have a function that the above-mentioned organic pigment and an anchoring site are bonded together and a compatible moiety extends into a dispersion medium to form a dispersion. However, this alkali-soluble resin is exclusively used for the purpose of removing an unexposed portion of the photosensitive composition using a feature that this alkali-soluble resin is dissolved when being in contact with an alkali.

Examples of the photopolymerizable monomer include difunctional monomers such as 1,6-hexanediol di(meth)acrylate, ethylene glycol di(meth)acrylate, neopentyl glycol di(meth)acrylate, triethylene glycol di(meth)acrylate, bis [(meth)acryloxyethoxy)]bisphenol A, and 3-methylpentanediol di(meth)acrylate; polyfunctional monomers, such as trimethylolpropane tri(meth)acrylate, pentaerythritol tri(meth)acrylate, tris(2-hydroxyethyl)isocyanurate tri(meth)acrylate, dipentaerythritol hexa(meth)acrylate, dipentaerythritol penta(meth)acrylate, and ditrimethylolpropane tetra(meth)acrylate, having a relatively low molecular weight; and polyfunctional monomers, such as polyester acrylate, polyurethane acrylate, and polyether acrylate, having a relatively high molecular weight. Similarly to the above, the term “(meth)acrylate” is a generic name for acrylate and methacrylate.

In particular, in order to increase the heat resistance of a cured film, tetrafunctional to hexafunctional (meth)acrylates are preferably used.

Examples of the photopolymerization initiator include acetophenone, benzophenone, benzyl dimethyl ketal, benzoyl peroxide, 2-chlorothioxanthone, 1,3-bis(4′-azidobenzal)-2-propane, 1,3-bis(4-azidobenzal)-2-propane-2′-sulfonic acid, 4,4′-diazidostilbene-2,2′-disulfonic acid, and ethanone, I-{9-ethyl-6-[2-methyl-4-(2,2-dimethyl-1,3-dioxolanyl)methoxybenzoyl]-9.H.-carbazol-3-yl}-, 1-(O-acetyloxime).

The photosensitive composition is a coloring material and therefore a photopolymerization initiator with excellent curability is preferably used.

The photosensitive composition, which has such characteristics, can be obtained in such a manner that three parts to 20 parts of a combination of the alkali-soluble resin and the photopolymerizable monomer, 0.05 parts to three parts of the photopolymerization initiator per one part of the photopolymerizable monomer, and the organic solvent used to prepare the above-mentioned coloring composition as required are added to 100 parts of the coloring composition according to the present invention, followed by uniform stirring and dispersing. The photosensitive composition can be used to form the black matrix section.

In order to form the black matrix by the photolithographic system, the photosensitive composition according to the present invention is preferably prepared so as to have a non-volatile matter content of at least 5% to 20% by mass for the purpose of allowing the photosensitive composition to have low viscosity, excellent application properties, and excellent workability.

A developer used may be a known common aqueous alkali solution. In particular, since the photosensitive composition contains the alkali-soluble resin, washing with the aqueous alkali solution is effective in forming the black matrix section. The excellent heat resistance of the photosensitive composition according to the present invention is exhibited in a method for manufacturing the color filter by performing firing after such alkali washing.

Among pigment dispersion methods, the method for manufacturing the color filter by the photolithographic method has been described in detail. The color filter may be manufactured in such a manner that the black matrix section, which is prepared using the photosensitive composition according to the present invention, is formed by another method such as an electrodeposition method, a transfer method, a micellar disruption method, or a PVED (photo-voltaic electro-deposition method).

The color filter can be obtained by a method in which color photosensitive compositions obtained using a red organic pigment, a green organic pigment, a blue organic pigment, and the coloring composition according to the present invention are used; a liquid crystal material is sealed between a pair of parallel transparent electrodes; the transparent electrodes are divided into discrete micro-zones; and color filter colored pixel sections with a color selected from red (R), green (G), and blue (B) are provided in each of the micro-zones partitioned into grids with black matrixes on the transparent electrodes in an alternate pattern or in such a manner that after the color filter colored pixel sections are formed on a substrate, the transparent electrodes are provided.

The black matrix section, which is obtained from the photosensitive composition according to the present invention, is such that the above-mentioned color organic pigments are contained so as to appear black. At first glance, it seems that a black matrix is obtained similarly to a case where a black photosensitive composition is prepared by mixing color photosensitive compositions. In the present invention, the color organic pigments are mixed together in advance when the coloring composition that is in the stage before being converted into the photosensitive composition is prepared. As a result, more uniform mixing is achieved and a black matrix with more excellent characteristics is obtained.

### EXAMPLES

The present invention is described below with reference to examples. The present invention is not limited thereby. In the examples and comparative examples, “parts” and “%” are on a mass basis unless otherwise specified. A cured pattern was prepared as a model for evaluating a color filter including a light-shielding member such as a black matrix.

### Example 1

### <Step of Preparing Coloring Composition>

Coloring Composition (A-1) was obtained in such a manner that 17 parts of Paliogen Blue L6360 (produced by BASF Company, C.I. Pigment Blue 60, a colorant), 22 parts of BYK LPN-21116 (produced by BYK Chemie Japan K.K., an acrylic resin-type dispersant having a basic group, a solid content of 40%), one part of anthraquinone-2-carboxylic acid (produced by Tokyo Chemical Industry Co., Ltd., an additive), and 109 parts of propylene glycol monomethyl ether acetate (produced by Kuraray Trading Co., Ltd., an organic solvent) were mixed together and 0.2-0.3 mm 9 zirconia beads were added, followed by dispersing for two hour using a paint conditioner (manufactured by Toyo Seiki Co., Ltd.).

<Step of Preparing Photosensitive Composition>

Photosensitive Composition (B-1) was prepared in such a manner that 100 parts of Coloring Composition (A-1), five parts of a methacrylic acid/mono(2-methacryloyloxyethyl) succinate/N-phenylmaleimide/styrene/benzyl methacrylate copolymer (copolymerization mass ratio=25/10/30/20/15, Mw=12,000, Mn=6,500) serving as an alkali-soluble resin, ten parts of dipentaerythritol hexaacrylate serving as a photopolymerizable monomer, one part of ethanone, 1-{9-ethyl-6-[2-methyl-4-(2,2-dimethyl-1,3-dioxolanyl)methoxybenzoyl]-9.H.-carbazol-3-yl}-, 1-(O-acetyloxime) serving as a photopolymerization initiator, 25 parts of dipropylene glycol dimethyl ether serving as an organic solvent, 25 parts of propylene glycol monomethyl ether acetate, 75 parts of 3-methoxybutyl acetate, and 50 parts of cyclohexanone were mixed together.

<Step of Preparing Cured Pattern>

A 10 cm square glass substrate (a glass plate, “OA-10”, manufactured by Nippon Electric Glass Co., Ltd., for color filters) was immersed in a 1% diluted solution of a silane coupling agent, “KB-603”, produced by Shin-Etsu Chemical Co., Ltd. for three minutes, was water-washed for ten seconds, was drained using an air gun, and was then dried at 110° C. for five minutes in an oven. Photosensitive Composition (B-1) prepared as described above was applied to the class substrate using a spin coater. After being vacuum-dried for one minute, the glass substrate was heat-dried at 90° C. for 90 seconds on a hotplate, whereby a coating film with a dry thickness of about 3.5 μm was obtained. Thereafter, image exposure was performed from the coating film side through a patterning mask with 15 μm wide fine lines. An exposure condition was 50 mJ/cm² (an i line basis) using a 3 kW high-pressure mercury lamp. Next, shower development was performed at 23° C. with a water pressure of 0.15 MPa using a developer made of an aqueous solution containing 0.05% of potassium hydroxide and 0.08% of a nonionic surfactant (“A-60” produced by Kao Corporation), followed by stopping development with pure water and washing using a water washing spray, whereby Cured Pattern (C-1) was obtained. Incidentally, the shower development time was adjusted between ten seconds and 120 seconds so as to be 1.5 times the time taken to dissolve off unexposed portions of the coating film.

### Example 2

Coloring Composition (A-2) was obtained by performing substantially the same operation as that used in Example 1 except that one part of the additive anthraquinone-2-carboxylic acid in Example 1 was changed to one part of sodium anthraquinone-2-sulfonate monohydrate (produced by Tokyo Chemical Industry Co., Ltd., an additive). Cured Pattern (C-2) was obtained by performing substantially the same operation as that used in Example 1 except that Coloring Composition (A-1) was changed to Coloring Composition (A-2).

### Example 3

Coloring Composition (A-3) was obtained by performing substantially the same operation as that used in Example 1 except that 22 parts of the dispersant BYK LPN-21116 in Example 1 was changed to 15 parts of BYK LPN-6919 (produced by BYK Chemie Japan K.K., an acrylic resin-type dispersant having a basic group, a solid content of 60%), one part of the additive anthraquinone-2-carboxylic acid was changed to one part of sodium anthraquinone-2-sulfonate monohydrate, and 109 parts of propylene glycol monomethyl ether acetate was changed to 116 parts. Cured Pattern (C-3) was obtained by performing substantially the same operation as that used in Example 1 except that Coloring Composition (A-1) was changed to Coloring Composition (A-3).

### Example 4

Coloring Composition (A-4) was obtained by performing substantially the same operation as that used in Example 1 except that 17 parts of the colorant Paliogen Blue L6360 in Example 1 was changed to 17 parts of Cibanon Blue GF (produced by Ciba Specialty Chemicals Corporation, C.I. Vat Blue 6). Cured Pattern (C-4) was obtained by performing substantially the same operation as that used in Example 1 except that Coloring Composition (A-1) was changed to Coloring Composition (A-4).

### Comparative Example 1

Coloring Composition (A-5) was obtained by performing substantially the same operation as that used in Example 1 except that 17 parts of the colorant Paliogen Blue L6360 in Example 1 was changed to 18 parts and one part of the additive anthraquinone-2-carboxylic acid was changed to zero parts. Cured Pattern (C-5) was obtained by performing substantially the same operation as that used in Example 1 except that Coloring Composition (A-1) was changed to Coloring Composition (A-5)

### Comparative Example 2

Coloring Composition (A-6) was obtained by performing substantially the same operation as that used in Example 1 except that 17 parts of the colorant Paliogen Blue L6360 in Example 1 was changed to 18 parts, 22 parts of the dispersant BYK LPN-21116 was changed to 15 parts of BYK LPN-6919, one part of the additive anthraquinone-2-carboxylic acid was changed to zero parts, and 109 parts of propylene glycol monomethyl ether acetate was changed to 116 parts. Cured Pattern (C-6) was obtained by performing substantially the same operation as that used in Example 1 except that Coloring Composition (A-1) was changed to Coloring Composition (A-6).

### Comparative Example 3

Coloring Composition (A-7) was obtained by performing substantially the same operation as that used in Example 1 except that one part of the additive anthraquinone-2-carboxylic acid in Example 1 was changed to one part of sodium anthraquinone-1-sulfonate (produced by Tokyo Chemical Industry Co., Ltd., an additive). Cured Pattern (C-7) was obtained by performing substantially the same operation as that used in Example 1 except that Coloring Composition (A-1) was changed to Coloring Composition (A-7).

### Comparative Example 4

Coloring Composition (A-8) was obtained by performing substantially the same operation as that used in Example 1 except that one part of the additive anthraquinone-2-carboxylic acid in Example 1 was changed to one part of disodium anthraquinone-2,6-disulfonate (produced by Tokyo Chemical Industry Co., Ltd., an additive). Cured Pattern (C-8) was obtained by performing substantially the same operation as that used in Example 1 except that Coloring Composition (A-1) was changed to Coloring Composition (A-8).

### Comparative Example 5

Coloring Composition (A-9) was obtained by performing substantially the same operation as that used in Example 1 except that 17 parts of the colorant Paliogen Blue L6360 in Example 1 was changed to 18 parts, one part of the additive anthraquinone-2-carboxylic acid was changed to zero parts, and 109 parts of propylene glycol monomethyl ether acetate was changed to 109 parts of isopropyl alcohol (produced by Tokyo Chemical Industry Co., Ltd., an organic solvent). Cured Pattern (C-9) was obtained by performing substantially the same operation as that used in Example 1 except that Coloring Composition (A-1) was changed to Coloring Composition (A-9)

### Comparative Example 6

Coloring Composition (A-10) was obtained by performing substantially the same operation as that used in Example 1 except that one part of the additive anthraquinone-2-carboxylic acid in Example 1 was changed to one part of sodium anthraquinone-2-sulfonate monohydrate and 109 parts of propylene glycol monomethyl ether acetate was changed to 109 parts of isopropyl alcohol. Cured Pattern (C-10) was obtained by performing substantially the same operation as that used in Example 1 except that Coloring Composition (A-1) was changed to Coloring Composition (A-10).

### Comparative Example 7

Coloring Composition (A-11) was obtained by performing substantially the same operation as that used in Example 1 except that one part of the additive anthraquinone-2-carboxylic acid in Example 1 was changed to one part of sodium anthraquinone-1-sulfonate and 109 parts of propylene glycol monomethyl ether acetate was changed to 109 parts of isopropyl alcohol. Cured Pattern (C-11) was obtained by performing substantially the same operation as that used in Example 1 except that Coloring Composition (A-1) was changed to Coloring Composition (A-11).

### Comparative Example 8

Coloring Composition (A-12) was obtained by performing substantially the same operation as that used in Example 1 except that one part of the additive anthraquinone-2-carboxylic acid in Example 1 was changed to one part of SOLSPERSE 12000 (produced by Japan Lubrizol Corporation, an additive), which was a copper phthalocyaninesulfonate derivative. Cured Pattern (C-12) was obtained by performing substantially the same operation as that used in Example 1 except that Coloring Composition (A-1) was changed to Coloring Composition (A-12).

### Comparative Example 9

Coloring Composition (A-13) was obtained by performing substantially the same operation as that used in Example 1 except that 17 parts of the colorant Paliogen Blue L6360 in Example 1 was changed to 18 parts of FASTOGEN SUPER RED ATY-TR (produced by DIC Corporation, C.I. Pigment Red 177, a colorant), 22 parts of the dispersant BYK LPN-21116 was changed to 15 parts of BYK LPN-6919, one part of the additive anthraquinone-2-carboxylic acid was changed to zero parts, and 109 parts of propylene glycol monomethyl ether acetate was changed to 116 parts. Cured Pattern (C-13) was obtained by performing substantially the same operation as that used in Example 1 except that Coloring Composition (A-1) was changed to Coloring Composition (A-13).

### Comparative Example 10

Coloring Composition (A-14) was obtained by performing substantially the same operation as that used in Example 1 except that 17 parts of the colorant Paliogen Blue L6360 in Example 1 was changed to 17 parts of FASTOGEN SUPER RED ATY-TR, 22 parts of the dispersant BYK LPN-21116 was changed to 15 parts of BYK LPN-6919, one part of the additive anthraquinone-2-carboxylic acid was changed to one part of sodium anthraquinone-2-sulfonate monohydrate, and 109 parts of propylene glycol monomethyl ether acetate was changed to 116 parts. Cured Pattern (C-14) was obtained by performing substantially the same operation as that used in Example 1 except that Coloring Composition (A-1) was changed to Coloring Composition (A-14)

<Evaluation>

### ⋅Viscosity

Coloring Compositions (A-1) to (A-14) obtained in Examples 1 to 4 and Comparative Examples 1 to 10 were measured for viscosity at 30 rpm using an E-type viscometer (TVE-25L, manufactured by Toki Sangyo CO., Ltd.). In Viscosity System 1 in which BYK LPN-21116 was used as a dispersant, the value of Example 2 was converted into 100 and was listed in the table below. In Viscosity System 2 in which BYK LPN-6919 was used as a dispersant and C.I. Pigment Blue 60 was used as a colorant, the value of Example 3 was converted into 100 and was listed in the table below. In Viscosity System 3 in which BYK LPN-6919 was used as a dispersant and C.I. Pigment Red 177 was used as a colorant, the value of Comparative Example 9 was converted into 100 and was listed in the table below.

⋅Degree of Cure

Results obtained by visually checking the presence or absence of a pattern defect in Cured Patterns (C-1), (C-2), (C-5), and (C-12) obtained in Example 1, Example 2, Comparative Example 1, and Comparative Example 8 (the degree of cure of one having no defect was rated ∘ and the degree of cure of one having a defect was rated x) were listed in the table below in the form of the degree of cure.

⋅Determination of Change in Hue

The absorption spectrum of each of Cured Patterns (C-1), (C-2), (C-5), and (C-12) obtained in Example 1, Example 2, Comparative Example 1, and Comparative Example 8 was measured with a spectrophotometer (U3900, manufactured by Hitachi High-Tech Science Corporation), the spectral width (long wavelength-side wavelength ram-short wavelength-side wavelength nm) at an absorption intensity equal to half the peak intensity of the absorption spectrum was calculated, and the increment from the value of Comparative Example 1, in which no additive was added, was listed in the table below in the form of the increment of the full width at half maximum.

Results are shown in Table 1.

TABLE 1

| | | | | | | | | | Increment of |
|---|---|---|---|---|---|---|---|---|---|
| | | | | | Viscosity | | | | full width at |
| | | | | Organic | System | System | System | Degree | half maximum |
| | Colorant | Dispersant | Additive | solvent | 1 | 2 | 3 | of cure | (nm) |
| Example 1 | PB60 | 21116 | AQ-2-COOH | PMA | 67 | — | — | ∘ | 1 |
| Example 2 | PB60 | 21116 | AQ-2- | PMA | 100 | — | — | ∘ | 2 |
| | | | SO₃Na•H₂O | | | | | | |
| Example 3 | PB60 | 6919 | AQ-2- | PMA | — | 100 | — | — | — |
| | | | SO₃Na•H₂O | | | | | | |
| Example 4 | VB6 | 21116 | AQ-2-COOH | PMA | 68 | — | — | — | — |
| Comparative | PB60 | 21116 | — | PMA | >400 | — | — | ∘ | 0 |
| Example 1 | | | | | | | | | |
| Comparative | PB60 | 6919 | — | PMA | — | 141 | — | — | — |
| Example 2 | | | | | | | | | |
| Comparative | PB60 | 21116 | AQ-1-SO₃Na | PMA | >400 | — | — | — | — |
| Example 3 | | | | | | | | | |
| Comparative | PB60 | 21116 | AQ-2,6- | PMA | >400 | — | — | — | — |
| Example 4 | | | (SO₃Na)₂ | | | | | | |
| Comparative | PB60 | 21116 | — | IPA | >400 | — | — | — | — |
| Example 5 | | | | | | | | | |
| Comparative | PB60 | 21116 | AQ-2- | IPA | >400 | — | — | — | — |
| Example 6 | | | SO₃Na•H₂O | | | | | | |
| Comparative | PB60 | 21116 | AQ-1- | IPA | >400 | — | — | — | — |
| Example 7 | | | SO₃Na | | | | | | |
| Comparative | PB60 | 21116 | S12000 | PMA | 166 | — | — | x | 10 |
| Example 8 | | | | | | | | | |
| Comparative | R177 | 6919 | — | PMA | — | — | 94 | — | — |
| Example 9 | | | | | | | | | |
| Comparative | R177 | 6919 | AQ-2- | PMA | — | — | 100 | — | — |
| Example 10 | | | SO₃Na•H₂O | | | | | | |

Abbreviations and the like in the table are summarized below.

PB60: C.I. Pigment Blue 60

21116: BYK LPN-21116

AQ-2-COOH: Anthraquinone-2-carboxylic acid

AQ-2-SO₃Na.H2O: Sodium anthraquinone-2-sulfonate monohydrate

AQ-1-SO₃Na: Sodium anthraquinone-1-sulfonate

AQ-2,6-(SO₃Na)₂: Disodium anthraquinone-2,6-disulfonate

S12000: SOLSPERSE 12000

PMA: propylene glycol monomethyl ether acetate

IPA: Isopropyl alcohol
In examples in which BYK LPN-21116 and propylene glycol monomethyl ether acetate are used, the addition of anthraquinone-2-carboxylic acid (Example 1) and the addition of sodium anthraquinone-2-sulfonate monohydrate (Example 2) give much lower viscosity as compared to no addition (Comparative Example 1), the addition of sodium anthraquinone-1-sulfonate (Comparative Example 3), and the addition of disodium anthraquinone-2,6-disulfonate (Comparative Example 4). It is clear that the addition of a 2-position mono-substituted compound is advantageous. In particular, one in which anthraquinone-2-carboxylic acid is used as an additive (Example 1) has particularly low viscosity and is preferable.
In examples in which BYK LPN-21116 and propylene glycol monomethyl ether acetate are used, the addition of sodium anthraquinone-2-sulfonate monohydrate (Example 2) gives much lower viscosity as compared to no addition (Comparative Example 1) and the addition of sodium anthraquinone-1-sulfonate (Comparative Example 3). In examples in which BYK LPN-21116 and isopropyl alcohol are used, the addition of sodium anthraquinone-2-sulfonate monohydrate (Comparative Example 6), no addition (Comparative Example 5), and the addition of sodium anthraquinone-1-sulfonate (Comparative Example 7) give high viscosity, it is clear that usage in combination with a glycol organic solvent is advantageous.
In examples in which BYK LPN-6919 and polypropylene glycol monomethyl ether acetate are used, the addition of sodium anthraquinone-2-sulfonate monohydrate (Example 3) in an example containing Pigment Blue 60 gives significantly reduced viscosity as compared to no addition (Comparative Example 2). In examples containing Pigment Red 177, the addition of sodium anthraquinone-2-sulfonate monohydrate (Comparative Example 10) gives the same viscosity as that in no addition (Comparative Example 9) or slightly increased viscosity. It is clear that using a threne compound in combination with a specific anthraquinone derivative is advantageous.
In Example 1, in which anthraquinone-2-carboxylic acid is contained, and Example 2, in which sodium anthraquinone-2-sulfonate monohydrate is contained, as well as Comparative Example, in which no additive is contained, no pattern defect is observed. However, in Comparative Example 8, in which SOLSPERSE 12000 (copper phthalocyaninesulfonate) is contained, a pattern defect is observed. It is clear that adding an anthraquinone derivative to a coloring composition for forming a pattern is advantageous.
In Example 1, in which anthraquinone-2-carboxylic acid is contained, and Example 2, in which sodium anthraquinone-2-sulfonate monohydrate is contained, the increase of the full width at half maximum (a change in hue) from Comparative Example 1, in which no additive is contained, occurs very little. However, in Comparative Example 8, in which SOLSPERSE 12000 (copper phthalocyaninesulfonate) is contained, the full width at half maximum is significantly increased (hue is changed). It is clear that adding an anthraquinone derivative to a coloring composition is advantageous.

From the above, a coloring composition according to the present invention is a coloring composition in which a threne compound unlikely to be highly dispersed in an organic solvent is highly dispersed using a specific anthraquinone derivative, the threne compound, and a glycol organic solvent and which can be used without causing an undesirable influence such as a curing failure or a change in hue in a step of preparing a color filter. Using this enables an excellent color filter to be obtained.

1. A coloring composition containing an anthraquinone derivative represented by General Formula (1) below: 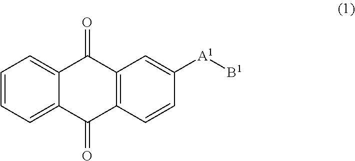
(in Formula (1), A¹ is a single bond, —CONH—R¹—, or —SO₂NH—R²—;
R¹ and R² are independently a divalent hydrocarbon group which may have a single bond or a substituent and which contains one to 20 carbon atoms; B¹ is —SO₃M.nH₂O or —COOM¹.nH₂O; M is one equivalent of a monovalent to trivalent cation; and n is an integer of 0 to 5), a threne compound represented by General Formula (2) below: 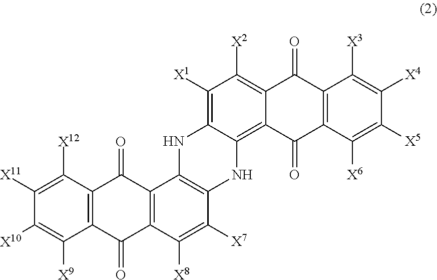
(in Formula (2), X¹ to X² are independently a hydrogen atom or a halogen atom), and a glycol organic solvent represented by General Formula (3) below: 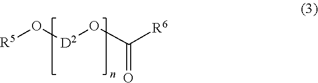
(in Formula (3), D² is a divalent hydrocarbon group which may have a substituent and which contains one to 20 carbon atoms, R⁵ is a monovalent hydrocarbon group which may have a hydrogen atom or a substituent, R⁶ is a monovalent hydrocarbon group which may have a substituent, and n is an integer of 1 to 5).

2. The coloring composition according to claim 1, wherein the threne compound is at least one selected from the group consisting of Pigment Blue 60, Vat Blue 4, Pigment Blue 64, and Vat Blue 6.

3. The coloring composition according to claim 1, wherein the anthraquinone derivative is a compound represented by General Formula (1-1) below: 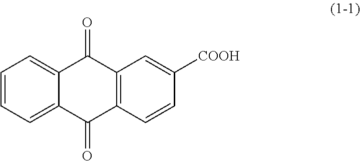
or a compound represented by General Formula (1-2) below:

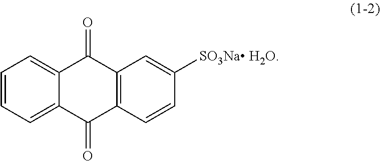

4. The coloring composition according to claim 1, wherein the glycol organic solvent is propylene glycol monomethyl ether acetate.

5. A color filter containing the coloring composition according to claim 1.
